(19) United States
(12) Patent Application Publication
(10) Pub. No.: US 2025/0369843 A1
(43) Pub. Date: Dec. 4, 2025

(54) METHOD AND TESTING SYSTEM FOR TESTING SEMICONDUCTOR CHIP PACKAGES

(71) Applicant: YANGTZE MEMORY TECHNOLOGIES CO., LTD., Wuhan (CN)

(72) Inventors: Guanshuai Wang, Wuhan (CN); Chao Wang, Wuhan (CN); Qi Xu, Wuhan (CN); Shaokai Rao, Wuhan (CN); Jianxiong Gong, Wuhan (CN); Mingchen Sun, Wuhan (CN); Yafei Fu, Wuhan (CN); Jinyu Tong, Wuhan (CN)

(21) Appl. No.: 18/741,091

(22) Filed: Jun. 12, 2024

Related U.S. Application Data
(63) Continuation of application No. PCT/CN2024/095734, filed on May 28, 2024.

(51) Int. Cl. G01N 3/02; G01R 31/28

(52) U.S. Cl. CPC G01N 3/02; G01R 31/2896

(57) ABSTRACT

Disclosed is an upper press head for mechanical testing and electrical testing of a semiconductor chip package. The upper press head includes: a force receiving component configured to receive a downward force; a force delivering component, having an upper portion connected with the force receiving component and having a first lateral sectional area, and a lower portion having a second lateral sectional area less than the first lateral sectional area; a force applying component connected with the lower portion of the force delivering component and configured to apply the downward force to the semiconductor chip package, the force applying component including: a plurality of protrusions that are laterally separated from each other and are configured to simultaneously press the semiconductor chip package; and a space between two adjacent protrusions matches portions of solder balls of the semiconductor chip package.

### CROSS-REFERENCE TO RELATED APPLICATIONS

This application is a continuation of International Application No. PCT/CN2024/095734, filed on May 28, 2024, which is hereby incorporated by reference in its entirety. This application is also related to U.S. Application No. ______, Attorney Docketing No.: 10018-01-0608-US, filed on even date, entitled “METHOD AND TESTING SYSTEM FOR TESTING SEMICONDUCTOR CHIP PACKAGES,” which is hereby incorporated by reference in its entirety.

### TECHNICAL FIELD

The present disclosure relates to the field of semiconductor technology, and more particularly, to a system and a method for testing semiconductor chip package.

### BACKGROUND

With the widespread adoption of 5G networks and the rapid development of big data and artificial intelligence (AI), the demand for storage from end customers has increased dramatically. This has necessitated continuous improvements in the capacity of individual packaging of semiconductor chips. Currently, there are two mainstream technologies for promoting packaging capacity. One approach is to increase the storage density of a single die, which requires advanced processing technology, high equipment standards, and results in high production costs. The other approach is to integrate more dies within a single packaging unit, which demands thinner dies for high stack packaging configurations.

### SUMMARY

In one aspect, the present disclosure provides an upper press head for mechanical testing and electrical testing of a semiconductor chip package. The upper press head includes a force receiving component configured to receive a downward force; a force delivering component, having an upper portion connected with the force receiving component and having a first lateral sectional area, and a lower portion having a second lateral sectional area less than the first lateral sectional area; and a force applying component connected with the lower portion of the force delivering component and configured to apply the downward force to the semiconductor chip package. The force applying component includes a plurality of protrusions that are laterally separated from each other and are configured to simultaneously press the semiconductor chip package and a space between two adjacent protrusions that matches portions of solder balls of the semiconductor chip package.

In some implementations, each protrusion includes a material having a hardness equal to or greater than HRc 60 as specified in ISO/DIS 6508-1 and coated with an insulating layer.

In some implementations, each protrusion includes a curved surface configured to be in contact with the semiconductor chip package, and the curved surface has a radius of curvature in a range of 0.3 mm and 2.0 mm.

In some implementations, the force applying component includes three protrusions that are configured to apply the downward force to the semiconductor chip package in three distinct areas, and the three protrusions are aligned and separated from each other along a first lateral direction. A first space between a left one of the three protrusions and a middle one of the three protrusions is equal to a second space between a right one of the three protrusions and the middle one of the three protrusions.

In some implementations, each protrusion has a length along the first lateral direction, a width along a second lateral direction being perpendicular to the first lateral direction, and a height along a vertical direction being perpendicular to both the first and second lateral directions; projections of the three protrusions on a plane defined by the first lateral direction and the vertical direction are three rectangles, where dimensions of a left one and a right one of the three rectangles along the first lateral direction are equal; and projections of the three protrusions on a plane defined by the second lateral direction and the vertical direction are overlapped and have a curved bottom line.

In some implementations, the force applying component includes five protrusions that are configured to apply the downward force to the semiconductor chip package in five distinct areas. The five protrusions are aligned and separated from each other along a first lateral direction, forming four spaces between every two adjacent protrusions. A first space has a first dimension, a second space has a second dimension, a third space has a third dimension, and a fourth space has a fourth dimension are sequentially aligned along the first lateral direction. The second dimension is equal to the third dimension, and the first dimension is equal to the fourth dimension.

In some implementations, each protrusion has a length along the first lateral direction, a width along a second lateral direction being perpendicular to the first lateral direction, and a height along a vertical direction being perpendicular to both the first and second lateral directions, and projections of the five protrusions on a plane defined by the first lateral direction and the vertical direction are five rectangles. Heights of the five rectangles are equal, a length of a first rectangle is same as a length of a fifth rectangle, a length of a second rectangle is same as a length of a fourth rectangle, and projections of the five protrusions on a plane defined by the second lateral direction and the vertical direction are overlapped and have a curved bottom line.

In another aspect, the present disclosure provides a socket for mechanical testing and electrical testing of a semiconductor chip package. The socket includes a cover having a set of openings; an array of conductive pins located inside the cover, configured to be in contact with solder balls of the semiconductor chip package for the electrical testing of the semiconductor chip package; and an upper press head. The upper press head includes a force receiving component configured to receive a downward force and a force applying component penetrating the cover through the set of openings, configured to apply the downward force to the semiconductor chip package.

In some implementations, the socket further includes a controlling apparatus connected to a mechanical testing sub-system and an electrical testing sub-system, and the controlling apparatus is configured to: in response to receiving a downward moving signal, control the upper press head to move downward at a constant downward speed; in response to receiving a suspending signal, stop moving the upper press head; and in response to receiving an upward moving signal, control the upper press head to move upward at a constant upward speed.

In some implementations, the socket further includes a printed circuit board (PCB) that is configured for wiring the array of conductive pins to the electrical testing sub-system.

In some implementations, the array of conductive pins are connected to the electrical testing sub-system via a USB interface.

In some implementations, the cover further includes a chip slot that is positioned corresponding to the array of conductive pins, configured for mounting the semiconductor chip package.

In some implementations, the set of openings include at least one of: a first subset openings arranged along a first lateral direction parallel to a longer edge of the cover; or a second subset openings arranged along a second lateral direction parallel to a shorter edge of the cover.

In some implementations, the array of conductive pins is able to form a pattern that matches a solder ball pattern of any one of: BGA 132 package; BGA 152 package; BGA 153 package; BGA 154 package; BGA 252 package; BGA 272 package; BGA 316 package; or BGA 315 package.

In some implementations, the chip slot has adjustable dimensions for accommodating any one of: BGA 132 package; BGA 152 package; BGA 153 package; BGA 154 package; BGA 252 package; BGA 272 package; BGA 316 package; or BGA 315 package.

In some implementations, the array of conductive pins are automatically and individually extendable or retractable with respect to the upper press head.

In some implementations, the force applying component has three protrusions aligned as a row along a first lateral direction and penetrating three openings of the set of openings of the cover, respectively, and configured to apply the downward force to the semiconductor chip package in three distinct areas.

In some implementations, the force applying component has five protrusions aligned as a row along a first lateral direction and penetrating five openings of the set of openings of the cover, respectively, and configured to apply the downward force to the semiconductor chip package in five distinct areas.

In some implementations, the force applying component has protrusions that are aligned as two rows along a first lateral direction.

In some implementations, the force applying component includes a material having a hardness equal to or greater than HRc 60 as specified in ISO/DIS 6508-1 and coated with an insulating layer.

In still another aspect, the present disclosure provides an integrated press head mechanically connected to a mechanical testing sub-system and electrically connected to an electrical testing sub-system, for mechanical testing and electrical testing of a semiconductor chip package. The integrated press head includes a force receiving component configured to receive a downward force; a force delivering component, having an upper portion connected with the force receiving component, and a lower portion connected with a force applying component; the force applying component configured to be in contact with the semiconductor chip package to apply the downward force to the semiconductor chip package; and an array of conductive pins configured to be in contact with solder balls of the semiconductor chip package, where a first portion of the array of conductive pins are extendable and retractable from the force applying component.

In some implementations, the downward force increases linearly as the force applying component moves downward on the semiconductor chip package.

In some implementations, a second portion of the array of conductive pins is located symmetrically to a third portion of the array of conductive pins with respect to the first portion of the array of conductive pins.

In some implementations, the lower portion of the force delivering component has a lower surface, the force applying component is attached to the lower surface, and the second and third portions of the array of conductive pins are extendable and retractable from the lower surface of the force delivering component.

In some implementations, the force applying component includes a curved surface; and an area of a projection of the force applying component on the lower surface of the force delivering component is greater than an area of a region in a lateral plane occupied by the first portion of the array of conductive pins.

In some implementations, the integrated press head further includes a printed circuit board (PCB), configured for wiring the array of conductive pins to the electrical testing sub-system.

In some implementations, the array of conductive pins are automatically and individually extendable and retractable with respect to the force applying component.

In some implementations, each conductive pin includes a curved end, and a curvature of the curved end is smaller than a curvature of a corresponding solder ball.

In some implementations, the array of conductive pins is able to form a pattern that matches a solder ball pattern of any one of BGA 132 package; BGA 152 package; BGA 153 package; BGA 154 package; BGA 252 package; BGA 272 package; BGA 316 package; or BGA 315 package.

In some implementations, the force applying component includes a material having a hardness equal to or greater than HRc 60 as specified in ISO/DIS 6508-1 and coated with an insulating layer.

### BRIEF DESCRIPTION OF THE DRAWINGS

The accompanying drawings, which are incorporated herein and form a part of the specification, illustrate implementations of the present disclosure and, together with the description, serve to explain the principles of the present disclosure and to enable a person skilled in the pertinent art to make and use the present disclosure.

FIG. 1a illustrates a block diagram of a testing system for testing semiconductor chip packages, in accordance with some implementations of the present disclosure.

FIG. 1b illustrates a perspective side view of an exemplary testing system, in accordance with some implementations of the present disclosure.

FIG. 2a-FIG. 2d show a process of loading a semiconductor chip package into a testing system, in accordance with some implementations of the present disclosure.

FIG. 2e and FIG. 2f are illustrative schemes of loading a semiconductor chip package onto a positioning plate, in accordance with some implementations of the present disclosure.

FIG. 3 illustrates a flowchart of an exemplary method performed by a testing system for testing a semiconductor chip package, in accordance with some implementations of the present disclosure.

FIG. 4a shows a first sideview of an exemplary upper press head, in accordance with some implementations of the present disclosure.

FIG. 4b shows a second sideview of an exemplary upper press head, in accordance with some implementations of the present disclosure.

FIG. 4c shows another exemplary upper press head, in accordance with some implementations of the present disclosure.

FIG. 5a shows an exemplary socket with openings that are arranged parallel to the shorter edge of a semiconductor chip package, in accordance with some implementations of the present disclosure.

FIG. 5b shows an exemplary socket with openings that are arranged parallel to the longer edge of a semiconductor chip package, in accordance with some implementations of the present disclosure.

FIG. 5c shows an exemplary socket with openings that are arranged parallel to both the shorter edge and longer edge of a semiconductor chip package, in accordance with some implementations of the present disclosure.

FIG. 5d shows an exemplary socket with an opening that is located in the middle of a socket, in accordance with some implementations of the present disclosure.

FIG. 5e shows an exemplary socket that has conductive pins that are in contact with solder balls of a semiconductor chip package, in accordance with some implementations of the present disclosure.

FIG. 5f shows an exemplary socket having conductive pins, in accordance with some implementations of the present disclosure.

FIG. 6a-FIG. 6d show exemplary patterns of solder ball arrangements, in accordance with some implementations of the present disclosure.

FIG. 7a shows an exemplary integrated press head, in accordance with some implementations of the present disclosure.

FIG. 7b shows the details of a force applying component and conductive pins of an exemplary integrated press head, in accordance with some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure, or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures, or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

Industry standards have clear specifications for the dimensions of individual packaging units, with limitations on the thickness of packaging units. Additionally, end manufacturers simulate mobile phone application scenarios to set specific strength specifications for individual packaging units. These specifications include testing the force and strain on the packaging unit without causing failure.

Integrating multiple dies within a single packaging unit can lead to a decline in the mechanical performance of the packaging, reducing its overall strength and its ability to resist bending deformation. Given the limited space available for chip packaging, factors such as die strength, packaging layout, epoxy molding compounds (EMC), and filler materials significantly influence the strain performance of the packaging unit. Currently, a three-point bending (3PB) testing method is commonly used for testing semiconductor chip packages. However, the commonly used 3PB testing method faces issues such as inconsistent testing results, long testing cycles, high costs, and the potential for underestimating packaging strain. In addition, when testing semiconductor chip packages, the mechanical properties and electrical properties need to be tested separately, which is time-consuming, requiring a large quantity of test samples and resulting in underestimation of packaging properties.

The present disclosure aims to address these challenges by providing a system and a method that integrates mechanical and electrical testing of semiconductor chip packages, ensuring a more efficient, accurate, and comprehensive evaluation of their performance.

The present disclosure provides a system and a method for simultaneous mechanical and electrical testing of semiconductor chip packages. This method can effectively determine the corresponding strain when a semiconductor chip package fails the electrical testing of its electrical functions, which reduces the number of test samples, significantly improves testing efficiency and the accuracy of packaging strain results, thereby effectively reducing testing costs.

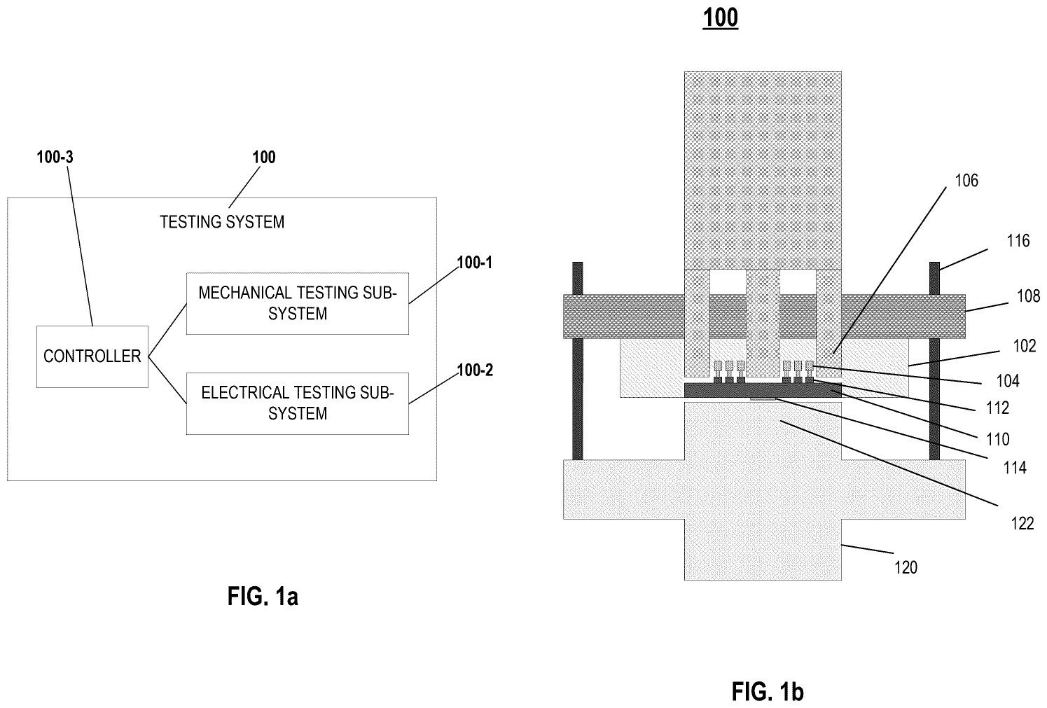

FIG. 1a illustrates a block diagram of a testing system for testing semiconductor chip packages. As shown in FIG. 1a, testing system 100, integrating both mechanical and electrical testing capabilities to evaluate a semiconductor chip package, may include a mechanical testing sub-system 100-1, an electrical testing sub-system 100-2, and a controller 100-3. The mechanical testing sub-system 100-1 is configured to perform mechanical tests on the semiconductor chip package. The mechanical testing sub-system 100-1 includes components that apply physical forces to the semiconductor chip package, such as upper press head, lower support, and strain gauges, to measure mechanical properties like strength and strain. The electrical testing sub-system 100-2 handles the electrical testing of the semiconductor chip package. The electrical testing sub-system 100-2 includes elements such as sockets and printed circuit boards to facilitate the measurement of electrical parameters and functionality of the semiconductor chip package. The controller 100-3 is the central unit that manages and coordinates the operations of both the mechanical and electrical testing sub-systems. The controller 100-3 ensures that the tests are conducted simultaneously or as required and processes the data collected from the tests. The controller 100-3 also monitors the preset trigger conditions and controls the transition between different testing stages.

FIG. 1b illustrates a schematic diagram in a perspective side view of an exemplary testing system 100, in accordance with some implementations of the present disclosure. Testing system 100 integrates a mechanical testing sub-system 100-1 and an electrical testing sub-system 100-2 to comprehensively evaluate the performance of the semiconductor chip package. As shown in FIG. 1b, testing system 100 can include socket 102, upper press head 106, printed circuit board 108, positioning post 116, and lower support 120. Socket 102 is a component of the electrical testing sub-system (as shown in FIG. 1a) and contains conductive pins 104 that are configured to contact with solder balls of a to-be-tested semiconductor chip package. The upper press head 106 is a component of the mechanical testing sub-system (as shown in FIG. 1a) and is configured to apply mechanical force to the to-be-tested semiconductor chip package during electrical testing of the to-be-tested semiconductor chip package. In some implementations, the upper press head 106 can be assembled onto the socket 102 by inserting a force applying component of the upper press head 106 into the socket 102. Under this situation, the upper press head 106 can be considered as a component of the socket 102. The upper press head 106 is positioned above the to-be-tested semiconductor chip package, and the upper press head 106 can move downward to apply force or move upwards. The printed circuit board 108 connects to the conductive pins 104 and facilitates electrical testing. The positioning post 116 helps align the socket 102 and the to-be-tested semiconductor chip package, ensuring that the socket 102 and upper press head 106 are correctly positioned relative to the to-be-tested semiconductor chip package. The lower support 120 includes a lower press head 122, which is configured to provide a stable base for the to-be-tested semiconductor chip package during testing, ensuring that the semiconductor chip package remains in place while force is applied by the upper press head 106.

Exemplarily, the to-be-tested semiconductor chip package can be semiconductor chip package 110 as shown in FIG. 1b. The semiconductor chip package 110 can be placed on the lower press head 122 of the lower support 120. One side of the semiconductor chip package 110 can be attached with strain gauge 114 and the other side of the semiconductor chip package 110 has solder balls 112. The strain gauge 114 can be wired to a strain meter (not shown in FIG. 1b), and strain data is recorded by the strain meter and transmitted to the controller 100-3. The solder balls 112 of the semiconductor chip package 110 can be in contact with conductive pins 104 for electrical testing, and electrical functions of the semiconductor chip package are transmitted to the controller 100-3. During the mechanical and electrical testing of the semiconductor chip package, each of the conductive pins 104 is individually and automatically extendable or retractable to keep electrical connection with solder balls 112 of the semiconductor chip package 110. In addition, the semiconductor chip package 110 can be in contact with the upper press head 106. When the upper press head 106 moves downwards, it causes the semiconductor chip package 110 to deform, which in turn causes the strain gauge 114 to deform. The deformation data of strain gauge 114 can be recorded and processed by the strain meter to generate strain data, which is transmitted to the controller 100-3. In some implementations, the deformation data of strain gauge 114 can be directly recorded and processed by the controller to generate strain data. In addition to the strain data, the moving rate of the upper press head 106, the force applied on the semiconductor chip package, and displacement data of the semiconductor chip package can be transmitted to and processed by the controller 100-3.

The controller 100-3 coordinates and manages the operations of both the mechanical testing sub-system 100-1 and the electrical testing sub-system 100-2 to ensure a synchronized evaluation of the semiconductor chip package. In some implementations, once the electrical properties, including open/short conditions, current/voltage parameters, and other performance metrics, of the semiconductor chip package are verified as pass, the controller 100-3 controls both the mechanical testing sub-system 100-1 and the electrical testing sub-system 100-2 to simultaneously conduct a first stage of mechanical testing and electrical testing on the semiconductor chip package, which ensures that both mechanical and electrical properties are assessed concurrently, providing a holistic view for both the mechanical and electrical performance of the semiconductor chip packages. In some implementations, the controller 100-3 controls the mechanical testing sub-system 100-1 to move the upper press head 106 to apply downward force to the semiconductor chip package, which causes first deforming of the semiconductor chip package. During the first deforming of the semiconductor chip package, data including moving rate of the upper press head 106, displacement of the semiconductor chip package, and strain of the semiconductor chip package are recorded. Simultaneously, the controller 100-3 also controls the electrical testing sub-system 100-2 to test electrical functions of the semiconductor chip package during the first deforming of the semiconductor chip package. The electrical functions may include open/short conditions of the semiconductor chip package, current/voltage parameters of the semiconductor chip package, and performance parameters of the semiconductor chip package. During the first deforming of the semiconductor chip package, each of the conductive pins 104 is automatically extendable or retractable to keep electrical connection with solder balls 112 of the semiconductor chip package 110.

In some implementations, upon determining that a preset trigger condition of either the mechanical testing or the electrical testing has been reached, the controller 100-3 switches the first stage of mechanical testing to a second stage of mechanical testing. The preset trigger condition of the mechanical testing may include at least one of: the force data reaching a force threshold value, the displacement data reaching a displacement threshold value, and the strain data reaching a strain threshold value. The preset trigger condition of the electrical testing may include at least one solder ball of the semiconductor chip package being short, at least one current/voltage parameter of the semiconductor chip package reaching a current/voltage threshold value, and at least one performance parameter of the semiconductor chip package reaching a performance threshold value. The performance parameter may be related to at least one of the following: 1) E-flash test, which tests functionality and performance of the embedded flash in the semiconductor chip package 110, including read/write operations, power consumption, and speed parameters; 2) Logic test, which tests the logic functions of the chip in the semiconductor chip package 110; 3) alternating current (AC) test, which verifies AC specifications, including the quality and timing sequence parameters of the AC output signals; or 4) Radio-frequency (RF) test, which tests the functionality and performance parameters of an RF module within the semiconductor chip package 110.

In some implementations, when the preset trigger condition is reached, the controller 100-3 is configured to control the mechanical testing sub-system 100-1 to stop moving the upper press head 106 downward and retract the upper press head 106 upward. In some implementations, when the preset trigger condition is reached, the controller 100-3 is configured to control the mechanical testing sub-system to maintain a position of the upper press head 106 for a period of time before retracting the upper press head 106 upward.

In some implementations, when the electrical function recovers after maintaining a position of the upper press head 106 for a period of time or after retracting the upper press head 106, the controller 100-3 is configured to control the mechanical testing sub-system 100-1 to move the upper press head 106 downward to cause second deforming of the semiconductor chip package. During the second deforming of the semiconductor chip package, data including moving rate of the upper press head 106, displacement of the semiconductor chip package, and strain of the semiconductor chip package are recorded. Simultaneously, the controller 100-3 also controls the electrical testing sub-system 100-2 to test electrical functions of the semiconductor chip package during the second deforming of the semiconductor chip package. The electrical functions may include open/short conditions of the semiconductor chip package, current/voltage parameters of the semiconductor chip package, and performance parameters of the semiconductor chip package. During the second deforming of the semiconductor chip package, each of the conductive pins 104 is automatically extendable or retractable to keep electrical connection with solder balls 112 of the semiconductor chip package 110.

In some implementations, during the first deforming of the semiconductor chip package, the upper press head 106 is controlled to move at a first downward rate, while during the second deforming of the semiconductor chip package, the upper press head 106 is controlled to move at a second downward rate that is less than the first downward rate.

In some implementations, during the first deforming of the semiconductor chip package, the upper press head 106 is controlled to apply a first downward force on the semiconductor chip package, while during the second deforming of the semiconductor chip package, the upper press head 106 is controlled to apply a second downward force that is less than the first downward force.

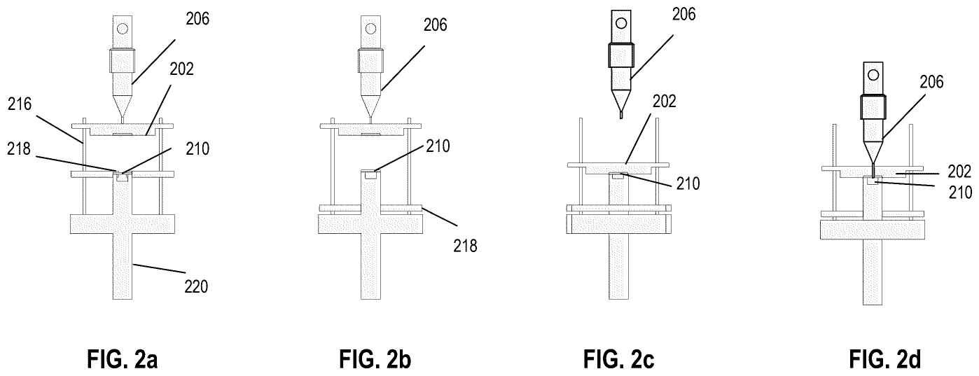

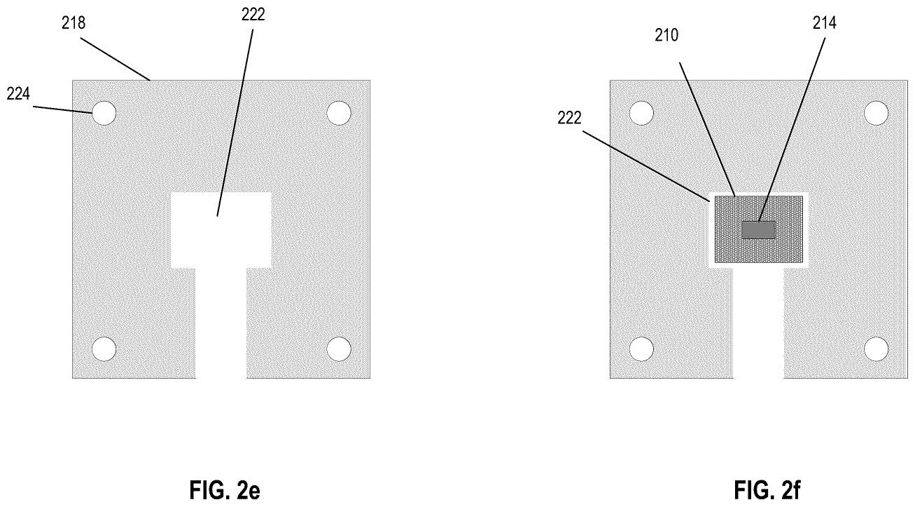

FIG. 2a-FIG. 2d show a process of loading a semiconductor chip package into a testing system, ensuring precise alignment and contact between the components for accurate mechanical and electrical testing, in accordance with some implementations of the present disclosure.

FIG. 2a depicts the initial setup for loading semiconductor chip package 210 into a testing system. As shown in FIG. 2a, the testing system may include upper press head 206, socket 202, positioning posts 216, positioning plate 218, and lower support 220. In some implementations, the upper press head 206 can be assembled onto the socket 202 by inserting a force applying component of the upper press head 206 into the socket 202. Under this situation, the upper press head 206 can be considered as a component of the socket 202.

In some implementations, the positioning plate 218 may include one or more positioning holes 224 and a positioning opening 222 as shown in FIG. 2e. Due to the presence of positioning holes 224 on the positioning plate 218, these positioning holes 224 allow the positioning posts 216 to pass through the positioning plate 218, enabling the positioning plate 218 to slide up and down along the positioning posts 216. By using the positioning holes 224, the positioning plate 218 can slide down along the positioning posts 216 and be placed onto the top of the lower support 220, so that the positioning opening 222 of the positioning plate 218 is coaxial and partially overlaps with the lower support 220. In some implementations, a tweezer can be used to place a semiconductor chip package 210 into the positioning opening 222 as shown in FIG. 2f. Except for conveniently and accurately placing the semiconductor chip package 210, the positioning opening 222 is also configured for conveniently attached strain gauge 214 (as shown in FIG. 2f) onto the semiconductor chip package 210. In some implementations, the positioning plate 218 may be made from a transparent material. The size of the positioning opening 222 is adjustable according to a size of a to-be-tested semiconductor chip package.

FIG. 2b illustrates the alignment of semiconductor chip package 210. The upper press head 206 and socket 202 may remain in their positions without movement. The positioning posts 216 ensure the proper alignment of the positioning plate 218. As the positioning plate 218 slides down along the positioning posts 216, the semiconductor chip package 210 is separated from the positioning opening 222 and positioned on the lower support 220.

FIG. 2c shows mounting the semiconductor chip package onto the socket 202. The upper press head 206 may remain stationary, while the socket 202 is lowered down along the positioning posts 216, moving towards the semiconductor chip package 210. In some implementations, when the upper press head 206 is integrated with the socket 202, the upper press head 206 moves along with the move of the socket 202. The positioning posts 216 guide the socket 202 as it descends until the socket 202 contacts the semiconductor chip package 210, while the semiconductor chip package 210 is maintained in position by the lower support 220.

FIG. 2d depicts the final positioning of the components for testing. The upper press head 206 is positioned above the semiconductor chip package 210, and force applying component of the upper press head 206 penetrates the socket 202 to contact the semiconductor chip package. The socket 202 is fully lowered, ensuring that the conductive pins contact the solder balls on the semiconductor chip package 210. The lower support 220 provides stable support throughout the testing process.

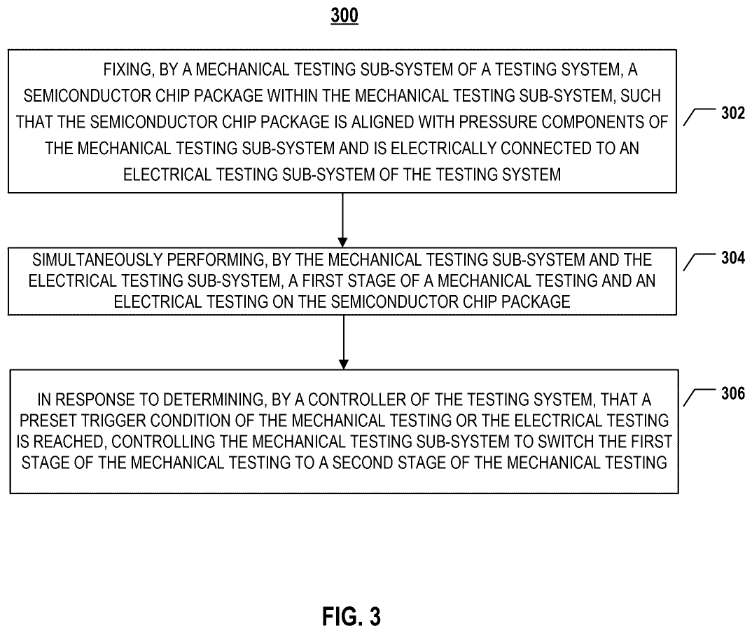

FIG. 3 illustrates a flowchart of a method 300 performed by a testing system for testing a semiconductor chip package. This method 300 involves coordinated operations of a mechanical testing sub-system (e.g., mechanical testing sub-system 100-1 as described above in connection with FIG. 1a) and an electrical testing sub-system (e.g., electrical testing sub-system 100-2 as described above in connection with FIG. 1a) under the control of a controller (e.g., controller 100-3 as described above in connection with FIG. 1a). The method 300 ensures simultaneous mechanical and electrical testing of the semiconductor chip package and transitions between different stages of mechanical testing based on preset trigger conditions.

In step 302, the method 300 involves fixing, by a mechanical testing sub-system of the testing system, a semiconductor chip package (e.g., semiconductor chip package 110 as described above in connection with FIG. 1b) within the mechanical testing sub-system. The semiconductor chip package is aligned with pressure components of the mechanical testing sub-system and is electrically connected to the electrical testing sub-system of the testing system. This alignment and connection ensure that the semiconductor chip package is properly positioned for subsequent mechanical and electrical testing.

In some implementations, the operation of fixing the semiconductor chip package within the mechanical testing sub-system may include mounting, by the mechanical testing sub-system, a socket (e.g., socket 102 as described above in connection with FIG. 1b) on the semiconductor chip package, such that conductive pins (e.g., conductive pins 104 as described above in connection with FIG. 1b) in the socket are in contact with solder balls (e.g., solder balls 112 as described above in connection with FIG. 1b) of the semiconductor chip package, where the semiconductor chip package is supported by a lower press head (e.g., lower press head 122 as described above in connection with FIG. 1b) of the pressure components, and the semiconductor chip package is attached with a strain gauge (e.g., strain gauge 114 as described above in connection with FIG. 1b).

In step 304, the method 300 includes simultaneously performing, by the mechanical testing sub-system and the electrical testing sub-system, a first stage of a mechanical testing and an electrical testing on the semiconductor chip package. During this stage, both the mechanical and electrical properties of the semiconductor chip package are assessed concurrently, providing comprehensive data on the performance of the semiconductor chip package.

In some implementations, the operation of simultaneously performing, by the mechanical testing sub-system and the electrical testing sub-system, the first stage of the mechanical testing and the electrical testing on the semiconductor chip package may include: moving, by the mechanical testing sub-system, an upper press head (e.g., upper press head 106 as described above in connection with FIG. 1b) of the pressure components to apply downward force to the semiconductor chip package to cause first deforming of the semiconductor chip package; recording, by the mechanical testing sub-system, mechanical data of the semiconductor chip package during the first deforming of the semiconductor chip package; and testing, by the electrical testing sub-system, an electrical function of the semiconductor chip package during the first deforming of the semiconductor chip package.

In some implementations, the operation of recording, by the mechanical testing sub-system, the mechanical data may include at least one of: recording force data of the semiconductor chip package, recording displacement data of the semiconductor chip package, and recording strain data of the semiconductor chip package.

In some implementations, the operation of testing, by the electrical testing sub-system, the electrical function may include testing at least one of: open/short conditions of the semiconductor chip package, current/voltage parameters of the semiconductor chip package, and performance parameters of the semiconductor chip package. The performance parameters may be related to at least one of the following: 1) E-flash test, which tests functionality and performance of the embedded flash in the semiconductor chip package, including read/write operations, power consumption, and speed parameters; 2) Logic test, which tests the logic functions of the chip in the semiconductor chip package; 3) alternating current (AC) test, which verifies AC specifications, including the quality and timing sequence parameters of the AC output signals; or 4) Radio-frequency (RF) test, which tests the functionality and performance parameters of an RF module within the semiconductor chip package.

In step 306, in response to determining, by the controller of the testing system, that a preset trigger condition of the mechanical testing or the electrical testing is reached, the method 300 involves controlling the mechanical testing sub-system to switch the first stage of the mechanical testing to a second stage of the mechanical testing. The preset trigger conditions may include specific force, displacement, or strain thresholds in the mechanical testing, or specific open/short conditions, current/voltage parameters, or performance parameters in the electrical testing.

In some implementations, the preset trigger condition of the mechanical testing may include at least one of: the force data reaching a force threshold value, the displacement data reaching a displacement threshold value, and the strain data reaching a strain threshold value.

In some implementations, the preset trigger condition of the electrical testing may include: at least one solder ball of the semiconductor chip package being short, at least one current/voltage parameter of the semiconductor chip package reaching a current/voltage threshold value, and at least one performance parameter of the semiconductor chip package reaching a performance threshold value.

In some implementations, the operation of controlling the mechanical testing sub-system to switch the first stage of the mechanical testing to the second stage of the mechanical testing may include: controlling, by the controller, the mechanical testing sub-system to stop moving the upper press head downward and retract the upper press head upward.

In some implementations, the operation of controlling the mechanical testing sub-system to switch the first stage of the mechanical testing to the second stage of the mechanical testing may include: controlling, by the controller, after controlling the mechanical testing sub-system to stop moving the upper press head downward and before controlling the mechanical testing sub-system to retract the upper press head upward, the mechanical testing sub-system to maintain a position of the upper press head for a period of time.

In some implementations, when the electrical function recovers, the method 300 may further include: controlling, by the controller, the mechanical testing sub-system to move the upper press head downward to cause second deforming of the semiconductor chip package; controlling, by the controller, the mechanical testing sub-system to record the mechanical data of the semiconductor chip package during the second deforming of the semiconductor chip package; and controlling, by the controller, the electrical testing sub-system to test the electrical function of the semiconductor chip package during the second deforming of the semiconductor chip package.

In some implementations, the method 300 may further include: controlling, by the controller, the mechanical testing sub-system to move the upper press head at a first downward rate to cause the first deforming of the semiconductor chip package; and controlling, by the controller, the mechanical testing sub-system to move the upper press head at a second downward rate less than the first downward rate to cause the second deforming of the semiconductor chip package.

In some implementations, the method 300 may include automatically extending or retracting the conductive pins during the first deforming of the semiconductor chip package to keep electric connections between the conductive pins and the solder balls of the semiconductor chip package.

In some aspects of the present disclosure, a non-transitory computer-readable storage medium is provided. The non-transitory computer-readable medium contains stored thereon computer-executable instructions that, when executed by a processor of a testing system, cause the processor to perform operations for testing a semiconductor chip package according to the foregoing described method. To avoid repetition, details are not described herein again. The non-transitory computer-readable storage medium is, for example, a Read-Only Memory (ROM), a Random Access Memory (RAM), a magnetic disk, or an optical disc.

The following disclosure focuses on the detailed description of the upper press head of the mechanical testing sub-system and the socket of the electrical testing sub-system.

The upper press head is a crucial component configured to apply force during the testing of a semiconductor chip package. Various implementations of the upper press head are provided to accommodate different testing needs, such as specific solder ball arrangements and electrical testing requirements. The upper press head may have a different number of protrusions that are configured to contact a to-be-tested semiconductor chip package. The number of protrusions of the upper press head can include but not limited to 1, 2, 3, 4, or 5, etc. In some implementations, the protrusion may be made from a material having a hardness equal to or greater than HRc 60 as specified in ISO/DIS 6508-1 and coated with an insulating layer.

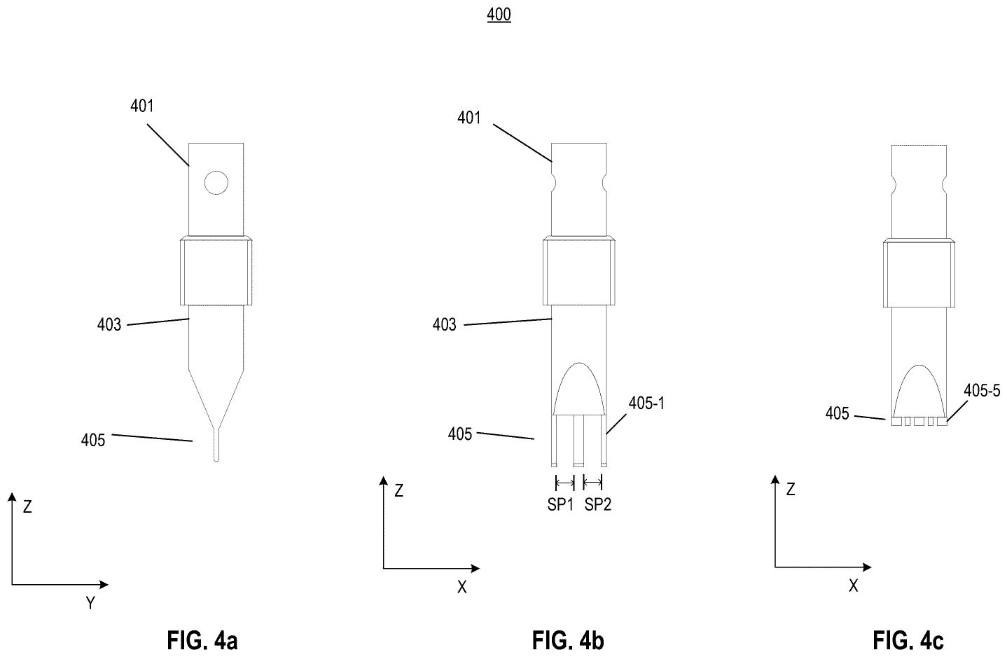

FIG. 4a and FIG. 4b depict a same upper press head from different perspectives, in accordance with some implementations of the present disclosure. As shown in FIG. 4a and FIG. 4b, upper press head 400 includes three main components: a force receiving component 401, a force delivering component 403, and a force applying component 405. The force receiving component 401 is located at the top of the upper press head 400 and is configured to receive force from an external source, such as a mechanical testing sub-system. The force receiving component 401 can be in the shape of a cylinder, but is not limited to a cylindrical shape. The force delivering component 403 transfers the force from the force receiving component to the force applying component 405. The force delivering component 403 can be in the shape of a cylinder, but is not limited to a cylindrical shape. The force applying component 405 is located at the lower end of the upper press head 400, is responsible for directly applying the force to a to-be-tested semiconductor chip package. A portion of the force applying component 405 that is in connection with the force delivering component 403 may be in the same shape as that of the force delivering component 403. In some implementations, as shown in FIG. 4b, the force applying component 405 may have three protrusions 405-1 that are aligned and separated from each other along a first lateral direction. These protrusions are aligned in a straight line, ensuring that the force is distributed evenly across the semiconductor chip package.

In some implementations, each protrusion may include a curved surface configured to be in contact with the to-be-tested semiconductor chip package. The curved surface may have a radius of curvature in a range of 0.3 mm and 2.0 mm.

In some implementations, a first space (SP1 as shown in FIG. 4b) between a left one of the three protrusions 405-1 and a middle one of the three protrusions 405-1 is equal to a second space (SP2 as shown in FIG. 4b) between a right one of the three protrusions 405-1 and the middle one of the three protrusions 405-1. In some implementations, each protrusion 405-1 has a length along the first lateral direction (i.e., X-direction as shown in FIG. 4b), a width along a second lateral direction (i.e., Y-direction as shown in FIG. 4a) being perpendicular to the first lateral direction, and a height along a vertical direction (i.e. Z-direction as shown in FIG. 4b) being perpendicular to both the first and second lateral directions. Projections of the three protrusions 405-1 on a plane (i.e., X-Z plane) defined by the first lateral direction and the vertical direction are three rectangles, where dimensions of a left one and a right one of the three rectangles along the first lateral direction are equal, and projections of the three protrusions on a plane (i.e., Y-Z plane) defined by the second lateral direction and the vertical direction are overlapped and have a curved bottom line.

In some implementations, a dimension of the force receiving component 401 along the vertical direction may be about 5˜30 mm, a dimension of the force receiving component 401 along the first lateral direction may be about 5˜20 mm, a dimension of the force applying component 405 along the vertical direction may be about 5˜30 mm, and a dimension of each protrusion along the vertical direction may be about 2˜20 mm.

FIG. 4c illustrates an upper press head where the force applying component is configured with five protrusions 405-5. As shown in FIG. 4c, five protrusions 405-5 are laterally spaced and aligned in a straight line. The five protrusions 405-5 are configured to apply a downward force to a to-be-tested semiconductor chip package in five distinct areas, which is beneficial for distributing force more evenly. The five protrusions 405-5 are aligned and separated from each other along a first lateral direction (i.e., X-direction as shown in FIG. 4c), forming four spaces between every two adjacent protrusions. A first space having a first dimension, a second space having a second dimension, a third space having a third dimension, and a fourth space having a fourth dimension are sequentially aligned along the first lateral direction. In some implementations, the second dimension is equal to the third dimension, and the first dimension is equal to the fourth dimension.

In some implementations, each protrusion 405-5 has a length along the first lateral direction, a width along a second lateral direction (i.e., Y-direction as shown in FIG. 4a) being perpendicular to the first lateral direction, and a height along a vertical direction (i.e., Z-direction as shown in FIG. 4c) being perpendicular to both the first and second lateral directions. Projections of the five protrusions on a plane defined by the first lateral direction and the vertical direction (i.e., X-Z plane) are five rectangles. In some implementations, heights of the five rectangles are equal, while a length of a first rectangle is the same as a length of a fifth rectangle, and a length of a second rectangle is the same as a length of a fourth rectangle. In some implementations, projections of the five protrusions on a plane defined by the second lateral direction and the vertical direction (i.e., Y-Z plane) overlap and have a curved bottom line.

In some implementations, a dimension of the force receiving component 401 along the vertical direction may be about 20.0 mm, a dimension of the force receiving component 401 along the first lateral direction may be about 12 mm, and a dimension of each protrusion of the five protrusions along the first lateral direction may be in a range of 0.5 mm to 2.5 mm. For example, along the first lateral direction, the first protrusion may have a dimension of 1.75 mm, the second protrusion may have a dimension of 0.5 mm, the third protrusion may have a dimension of 2.5 mm, the fourth protrusion may have a dimension of 0.5 mm, and the fifth protrusion may have a dimension of 1.75 mm. Along the vertical direction, the dimensions of the five protrusions may be the same, which is about 1.0 mm.

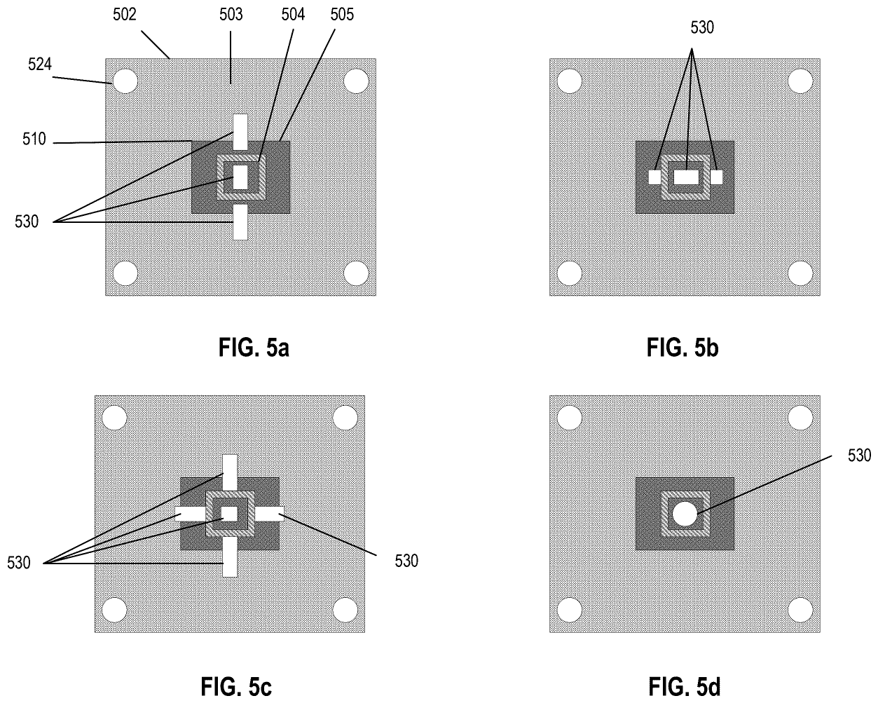

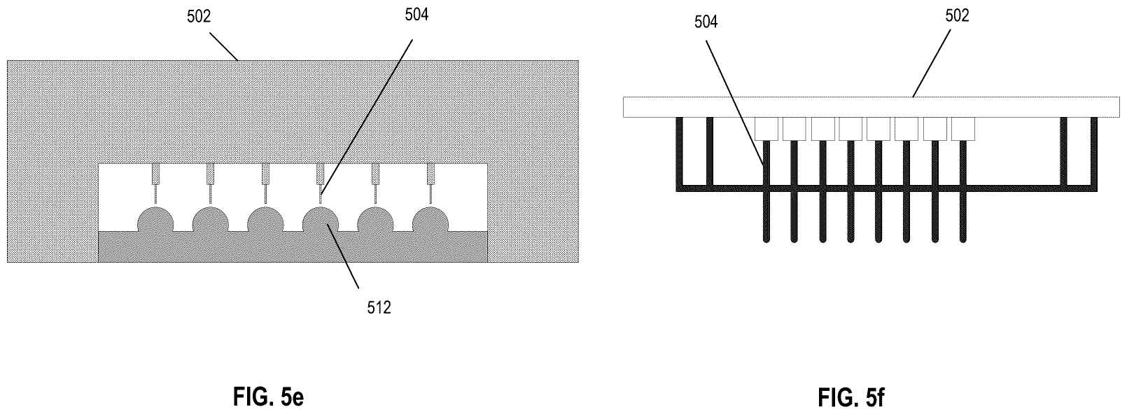

FIGS. 5a-5d illustrate various configurations of a socket configured to interface with a semiconductor chip package. The figures highlight different arrangements of socket openings and positioning features that facilitate secure mounting and testing of the semiconductor chip package. The socket remains the same across different figures, with variations only in the number and arrangement of socket openings.

FIG. 5a shows a top view of a socket 502, which is configured to interface with a semiconductor chip package 510. The socket 502 includes several key components, including: cover 503, conductive pins 504, socket positioning holes 524, and socket openings 530. The cover 503 includes a chip slot 505 configured for mounting the semiconductor chip package 510, and the chip slot 505 includes the conductive pins 504. When the semiconductor chip package 510 is mounted in the chip slot 505, each solder ball of the semiconductor chip package is in contact with one of the conductive pins of the socket 502. The cover 503 ensures that the semiconductor chip package 510 remains securely in place during testing. The conductive pins 504 are configured to make electrical contact with solder balls on the semiconductor chip package 510. The socket positioning holes 524 are located at the corners of socket 502 and are used for, in combination of positioning posts (such as positioning posts 116 as shown in FIG. 1), alignment and securing the socket 502 in place. Socket openings 530 are configured to allow the passing of an upper press head (for example, upper press head 106 as shown in FIG. 1) for applying force on the semiconductor chip package 510. In FIG. 5a, the socket 502 has three openings arranged parallel to the shorter edge of the semiconductor chip package 510. In FIG. 5b, the socket 502 has three openings arranged parallel to the longer edge of the semiconductor chip package 510. In FIG. 5c, the socket 502 has five openings arranged parallel to both the shorter and longer edges of the semiconductor chip package 510. In FIG. 5a, the socket 502 has a single opening on the center of socket 502. The differently arranged socket openings 530 allow upper press heads with different force applying components (i.e., upper press head with three protrusions as shown in FIG. 4b or upper press head with five protrusions as shown in FIG. 4c) to pass through.

Although FIGS. 5a-5d illustrate socket 502 having 1, 3, or 5 openings, the number of openings is not limited to 1, 3, or 5. For example, the number of openings can be 2, 4, 6, 7, 8, 9, or 10.

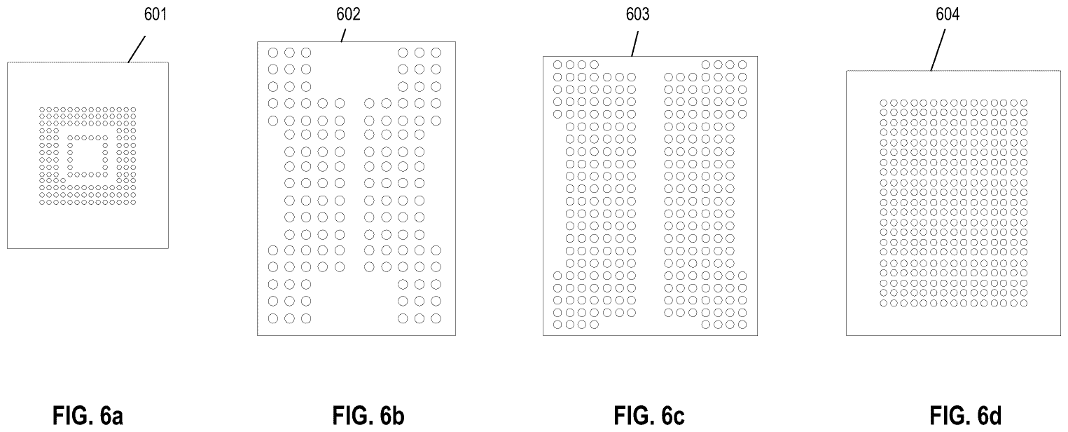

FIG. 5e presents a side cross-sectional view of socket 502, showing the interaction between the conductive pins 504 and solder balls 512 of the semiconductor chip package 510. The conductive pins 504 are integrated within the socket 502 and are configured to make electrical contact with the solder balls 512 of the semiconductor chip package 510. Each conductive pin 504 is aligned with a corresponding solder ball 512, ensuring a reliable electrical connection during the deformation of the semiconductor chip package 510. Each conductive pin 504 is extendable and retractable, so that it keeps good contact with its corresponding solder ball during the deforming of the semiconductor chip package 510. Solder balls 512 are part of the semiconductor chip package and provide the contact points for the conductive pins 504. The solder balls 512 can be arranged in any suitable patterns, such as patterns according to JESD230D standards of ball grid array (BGA) arrangement. For example, as shown in FIG. 6a-6d, the solder balls 512 can be arranged according to BGA 153 (pattern 601 as shown in FIG. 6a), BGA 132 (pattern 602 as shown in FIG. 6b), BGA 272 (pattern 603 as shown in FIG. 6c), or BGA 315 (pattern 604 as shown in FIG. 6d). In addition, the solder balls 512 can also be arranged according to BGA 132, BGA 152, BGA 153, BGA 154, BGA 252, BGA 272, or BGA 316.

FIG. 5f shows a front cross-sectional view of socket 502, further illustrating the details of the conductive pins 504. The conductive pins 504 are evenly spaced and aligned to match the layout of the solder balls on the semiconductor chip package. The conductive pins 504 are constructed from durable materials to withstand the mechanical and electrical stresses during testing. For example, conductive pins can be made from copper or a copper alloy. The conductive pins 504 can be customized to match various semiconductor chip package designs, ensuring versatility and adaptability in different testing scenarios. Each conductive pin 504 is configured to move independently. This independent movement of each conductive pin 504 allows each conductive pin 504 to adjust its position without affecting the other conductive pins 504. In some implementations, the independent movement of each conductive pin 504 is realized by a spring-loaded design, where each conductive pin 504 is equipped with a spring that allows it to compress or extend as needed. In some implementations, each conductive pin 504 is designed as a spring or a portion of each conductive pin 504 is designed as a spring.

In some implementations, the socket may integrate with an upper press head as shown in FIG. 1. The upper press head may include a force receiving component configured to receive a downward force and a force applying component penetrating the cover 503 through the socket openings 530, configured to apply the downward force to the semiconductor chip package 510. In some implementations, the conductive pins 504 are automatically and individually extendable or retractable with respect to the upper press head. In some implementations, the force applying component has three protrusions aligned as a row along a first lateral direction and penetrating three openings of the socket openings 530 of the cover 503, respectively, and configured to apply the downward force to the semiconductor chip package 510 in three distinct areas. In some implementations, the force applying component has five protrusions aligned as a row along a first lateral direction and penetrating five openings of the socket openings 530 of the cover 503, respectively, and configured to apply the downward force to the semiconductor chip package in five distinct areas. In some implementations, the force applying component has protrusions that are aligned as two rows along a first lateral direction. The force applying component may include a material having a hardness equal to or greater than HRc 60 as specified in ISO/DIS 6508-1 and coated with an insulating layer.

In some implementations, socket 502 may include a controlling apparatus connected to a mechanical testing sub-system and an electrical testing sub-system. The controlling apparatus is configured to: in response to receiving a downward moving signal, control the upper press head to move downward at a constant downward speed; in response to receiving a suspending signal, stop moving the upper press head; and in response to receiving an upward moving signal, control the upper press head to move upward at a constant upward speed.

In some implementations, socket 502 may include a printed circuit board (PCB) that is configured for wiring the conductive pins 504 to the electrical testing sub-system.

In some implementations, the conductive pins 504 are connected to the electrical testing sub-system via a USB interface.

In some implementations, the chip slot of the cover 503 has adjustable dimensions for accommodating any one of BGA 132 package, BGA 152 package, BGA 153 package, BGA 154 package, BGA 252 package, BGA 272 package, BGA 316 package, or BGA 315 package.

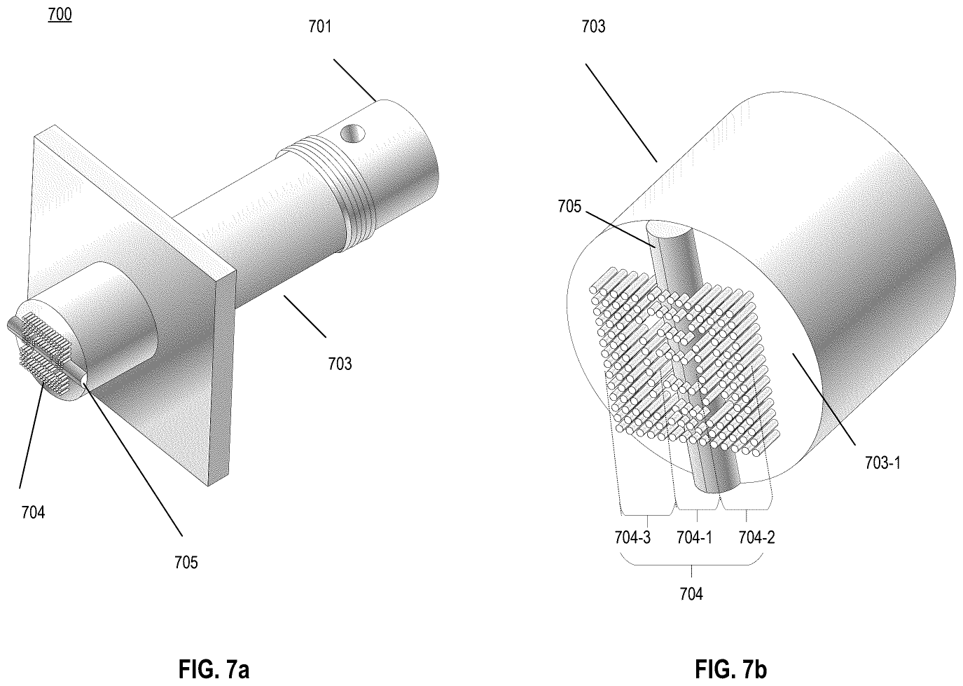

FIG. 7a and FIG. 7b illustrate an integrated press head configured for testing a semiconductor chip package. The integrated press head combines both mechanical and electrical testing functionalities. The design ensures that the force is applied accurately while maintaining electrical connections with the semiconductor chip package throughout the testing process.

FIG. 7a shows an exemplary integrated press head, in accordance with some implementations of the present disclosure. As shown in FIG. 7a, integrated press head 700 includes a force receiving component 701, a force delivering component 703, a force applying component 705, and an array of conductive pins 704. The force receiving component 701 is the part of the integrated press head that receives the applied downward force from the mechanical testing sub-system. This component is configured to withstand the downward force and distribute it to the force delivering component 703. The force receiving component 701 can be in the shape of a cylinder, but is not limited to a cylindrical shape. The force delivering component 703 has an upper portion that is connected to the force receiving component 701. The force delivering component 703 has a lower portion that is connected with force applying component 705, and is responsible for transferring the force to the force applying component 705. The force delivering component 703 can be in the shape of a cylinder, but is not limited to a cylindrical shape. The force applying component 705 is the part of the integrated press head that comes into direct contact with the semiconductor chip package, applying the downward force to the semiconductor chip package. The force applying component 705, as illustrated in FIG. 7b, has a curved surface on one side and a flat surface on the opposite side. The flat surface is in connection with the force delivering component 703, ensuring a secure attachment. The curved surface of the force applying component 705 is configured to apply force to the semiconductor chip package. This design allows the force applying component 705 to transfer force effectively from the force delivering component 703 to the semiconductor chip package, facilitating accurate and consistent mechanical testing.

As shown in FIG. 7a, the integrated press head 700 also includes multiple conductive pins 704 that ensure electrical connectivity with the solder balls of the semiconductor chip package. The array of conductive pins 704 are configured to be in contact with solder balls of the semiconductor chip package and establish/maintain electrical connections with the semiconductor chip package while the force is being applied.

FIG. 7b shows the details of a force applying component and conductive pins of an exemplary integrated press head, in accordance with some implementations of the present disclosure. Similar to FIG. 7a, the force receiving component 701 in FIG. 7b receives the applied force from the mechanical testing sub-system. The force delivering component 703 is illustrated here from a different perspective, showing how it connects to the force applying component 705. The array of conductive pins 704 and the force applying component 705 in FIG. 7b are shown with a detailed view. As shown in FIG. 7b, a first portion 704-1 of the array of conductive pins 704 are extendable and retractable from the force applying component 705, and a second portion 704-2 of the array of conductive pins 704 is located symmetrically to a third portion 704-3 of the array of conductive pins 704 with respect to the first portion of the array of conductive pins 704.

In some implementations, the lower portion of the force delivering component 703 has a lower surface 703-1. The force applying component 705 is attached to the lower surface 703-1 of the force delivering component 703, and the second and third portions of the array of conductive pins 704 are extendable and retractable from the lower surface of the force delivering component 703.

In some implementations, the force applying component 705 includes a curved surface, and an area of a projection of the force applying component on 705 on the lower surface of the force delivering component 703 is greater than an area of a region in a lateral plane occupied by the first portion of the array of conductive pins 704.

In some implementations, the downward force increases linearly as the force applying component 705 moves downward on the semiconductor chip package.

In some implementations, the integrated press head includes a printed circuit board (PCB), which is configured for wiring the conductive pins 704 to the electrical testing sub-system.

In some implementations, the array of conductive pins 704 are automatically and individually extendable and retractable with respect to the force applying component 705.

In some implementations, each conductive pin 704 includes a curved end, and a curvature of the curved end is smaller than a curvature of a corresponding solder ball.

In some implementations, the array of conductive pins 704 is able to form a pattern that matches a solder ball pattern of any one of: BGA 132 package; BGA 152 package; BGA 153 package; BGA 154 package; BGA 252 package; BGA 272 package; BGA 316 package; or BGA 315 package.

In some implementations, the force applying component includes a material having a hardness equal to or greater than HRc 60 as specified in ISO/DIS 6508-1 and coated with an insulating layer.

The foregoing description of the specific implementations will so fully reveal the general nature of the present disclosure that others can, by applying knowledge within the skill of the art, readily modify and/or adapt, for various applications, such specific implementations, without undue experimentation, and without departing from the general concept of the present disclosure. Therefore, such adaptations and modifications are intended to be within the meaning and range of equivalents of the disclosed implementations, based on the disclosure and guidance presented herein. It is to be understood that the phraseology or terminology herein is for the purpose of description and not of limitation, such that the terminology or phraseology of the present specification is to be interpreted by the skilled artisan in light of the disclosure and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all exemplary implementations of the present disclosure as contemplated by the inventor(s), and thus, are not intended to limit the present disclosure and the appended claims in any way.

The breadth and scope of the present disclosure should not be limited by any of the above-described exemplary implementations, but should be defined only in accordance with the following claims and their equivalents.

What is claimed is:

1. A upper press head for mechanical testing and electrical testing of a semiconductor chip package, comprising:
a force receiving component configured to receive a downward force;
a force delivering component, having an upper portion connected with the force receiving component and having a first lateral sectional area, and a lower portion having a second lateral sectional area less than the first lateral sectional area;
a force applying component connected with the lower portion of the force delivering component and configured to apply the downward force to the semiconductor chip package, the force applying component comprising:
a plurality of protrusions that are laterally separated from each other and are configured to simultaneously press the semiconductor chip package; and
a space between two adjacent protrusions matches portions of solder balls of the semiconductor chip package.

2. The upper press head according to claim 1, wherein:
each protrusion comprises a curved surface configured to be in contact with the semiconductor chip package; and
the curved surface has a radius of curvature in a range of 0.3 mm and 2.0 mm.

3. The upper press head according to claim 1, wherein:
the force applying component comprises three protrusions that are configured to apply the downward force to the semiconductor chip package in three distinct areas;
the three protrusions are aligned and separated from each other along a first lateral direction; and
a first space between a left one of the three protrusions and a middle one of the three protrusions is equal to a second space between a right one of the three protrusions and the middle one of the three protrusions.

4. The upper press head according to claim 3, wherein:
each protrusion has a length along the first lateral direction, a width along a second lateral direction being perpendicular to the first lateral direction, and a height along a vertical direction being perpendicular to both the first and second lateral directions;
projections of the three protrusions on a plane defined by the first lateral direction and the vertical direction are three rectangles, wherein dimensions of a left one and a right one of the three rectangles along the first lateral direction are equal; and
projections of the three protrusions on a plane defined by the second lateral direction and the vertical direction are overlapped and have a curved bottom line.

5. The upper press head according to claim 1, wherein:
the force applying component comprises five protrusions that are configured to apply the downward force to the semiconductor chip package in five distinct areas;
the five protrusions are aligned and separated from each other along a first lateral direction, forming four spaces between every two adjacent protrusions;
a first space having a first dimension, a second space having a second dimension, a third space having a third dimension, and a fourth space having a fourth dimension are sequentially aligned along the first lateral direction, wherein:
the second dimension is equal to the third dimension; and
the first dimension is equal to the fourth dimension.

6. The upper press head according to claim 5, wherein:
each protrusion has a length along the first lateral direction, a width along a second lateral direction being perpendicular to the first lateral direction, and a height along a vertical direction being perpendicular to both the first and second lateral directions;
projections of the five protrusions on a plane defined by the first lateral direction and the vertical direction are five rectangles, wherein:
heights of the five rectangles are equal, and
a length of a first rectangle is same as a length of a fifth rectangle, a length of a second rectangle is same as a length of a fourth rectangle; and
projections of the five protrusions on a plane defined by the second lateral direction and the vertical direction are overlapped and have a curved bottom line.

7. A socket for mechanical testing and electrical testing of a semiconductor chip package, comprising:
a cover, comprising a set of openings;
an array of conductive pins located inside the cover, configured to be in contact with solder balls of the semiconductor chip package for the electrical testing of the semiconductor chip package; and
an upper press head comprising:
a force receiving component configured to receive a downward force, and
a force applying component penetrating the cover through the set of openings, configured to apply the downward force to the semiconductor chip package.

8. The socket according to claim 7, further comprising a controlling apparatus connected to a mechanical testing sub-system and an electrical testing sub-system, wherein the controlling apparatus is configured to:
in response to receiving a downward moving signal, control the upper press head to move downward at a constant downward speed;
in response to receiving a suspending signal, stop moving the upper press head; and
in response to receiving an upward moving signal, control the upper press head to move upward at a constant upward speed.

9. The socket according to claim 7, wherein the cover further comprises a chip slot that is positioned corresponding to the array of conductive pins, configured for mounting the semiconductor chip package.

10. The socket according to claim 7, wherein the set of openings comprise at least one of:
a first subset openings arranged along a first lateral direction parallel to a longer edge of the cover; or
a second subset openings arranged along a second lateral direction parallel to a shorter edge of the cover.

11. The socket according to claim 7, wherein the array of conductive pins are automatically and individually extendable or retractable with respect to the upper press head.

12. The socket according to claim 7, wherein the force applying component has three protrusions aligned as a row along a first lateral direction and penetrating three openings of the set of openings of the cover, respectively, and configured to apply the downward force to the semiconductor chip package in three distinct areas.

13. The socket according to claim 7, wherein the force applying component has five protrusions aligned as a row along a first lateral direction and penetrating five openings of the set of openings of the cover, respectively, and configured to apply the downward force to the semiconductor chip package in five distinct areas.

14. The socket according to claim 7, wherein the force applying component has protrusions that are aligned as two rows along a first lateral direction.

15. An integrated press head, mechanically connected to a mechanical testing sub-system and electrically connected to an electrical testing sub-system, for mechanical testing and electrical testing of a semiconductor chip package, comprising:
a force receiving component configured to receive a downward force;
a force delivering component, having an upper portion connected with the force receiving component, and a lower portion connected with a force applying component;
the force applying component configured to be in contact with the semiconductor chip package to apply the downward force to the semiconductor chip package; and
an array of conductive pins configured to be in contact with solder balls of the semiconductor chip package,
wherein a first portion of the array of conductive pins are extendable and retractable from the force applying component.

16. The integrated press head according to claim 15, wherein the downward force increases linearly as the force applying component moves downward on the semiconductor chip package.

17. The integrated press head according to claim 15, wherein:
a second portion of the array of conductive pins is located symmetrically to a third portion of the array of conductive pins with respect to the first portion of the array of conductive pins.

18. The integrated press head according to claim 17, wherein:
the lower portion of the force delivering component has a lower surface;
the force applying component is attached to the lower surface; and
the second and third portions of the array of conductive pins are extendable and retractable from the lower surface of the force delivering component.

19. The integrated press head according to claim 18, wherein:
the force applying component comprises a curved surface; and
an area of a projection of the force applying component on the lower surface of the force delivering component is greater than an area of a region in a lateral plane occupied by the first portion of the array of conductive pins.

20. The integrated press head according to claim 15, wherein the array of conductive pins are automatically and individually extendable and retractable with respect to the force applying component.
